(19) United States
(12) Patent Application Publication
(10) Pub. No.: US 2008/0171154 A1
(43) Pub. Date: Jul. 17, 2008

(54) METHOD OF TREATMENT AND PROCESSING OF TOOLS FOR MACHINING OF WORKPIECES BY CUTTING

(76) Inventors: Josef Maushart, Solothum (CH); Tiziano Sichi, Luterbach (CH); Johan Rechberger, Utzigen (CH)

Correspondence Address: PEARNE & GORDON LLP, 1801 EAST 9TH STREET, SUITE 1200, CLEVELAND, OH, 44114-3108, US

(21) Appl. No.: 11/962,563

(22) Filed: Dec. 21, 2007

(30) Foreign Application Priority Data
Jan. 15, 2007 (EP) 07 10 0536.7

(51) Int. Cl. B05D 3/12; H05H 1/24; C23C 16/02

(52) U.S. Cl. 427/576; 427/289; 427/569; 427/577; 427/255.28

(57) ABSTRACT

A method of treatment and processing of tools for machining of workpieces by cutting is described, in particular milling tools. These tools are made up of a high-strength steel, carbide or ceramic, and are provided with at least one cutting flank and a flute, which cutting flank is provided with a cutting edge on the cutting side. In a coating installation, the tool is provided with a first coating which is wear-resistant against abrasion. Afterwards a bevel is ground on each of the cutting edges. A second coating, which is resistant to crater wear, is applied to the ground bevel in a coating installation. Tools are thereby obtained that are characterized by high abrasion resistance and high resistance to wear and tear, in particular during machining of difficult materials at high cutting speed.

This invention relates to a method for treatment and processing of tools for machining of workpieces by cutting, in particular milling tools, which tools are made up of a high-strength steel, carbide or ceramic, and are provided with at least one cutting flank and a flute, which cutting flank is provided with a cutting edge on the cutting side.

With cutting tools of this kind, in particular milling tools, high endurance is required. This means that the wear and tear on the tools should be kept as low as possible through suitable measures, even when the tools are used for increasingly more difficult materials to be machined and the cutting speeds become higher and higher, whereby these tools are subjected to greater stress.

It is known to provide these tools with a coating to improve their abrasion protection and hence increase service life. This coating consists, for example, of TiN (titanium nitride). The application of such a coating takes place in a known way through vaporization, for example through the PVD (physical vapor deposition) method. The tool thereby obtains a resistant coating with a thickness of some micrometers in the region of the cutting flanks and of the flutes and on the cutting edge. This coating offers good protection against abrasive wear and tear.

It has been shown, however, that with tools that have been provided with such a coating, the stresses on the cutting edges are very great and that, despite the coating, broken-off pieces can occur in the region of the cutting edges. Owing to these broken-off pieces, the geometry of the cutting edge changes, the chips can no longer flow correctly, the machining forces increase severely, and service life is reduced rapidly.

The object of the invention thus consists in creating a method for treatment and processing of tools, in particular milling tools, after the carrying out of which method abrasion and in particular the breaking off of pieces of the cutting edges can at least be limited in a completely general way.

This object is achieved according to the invention in that, in a coating installation, the tool is provided with a first coating that is resistant to flank wear (abrasive wear and tear), in that afterwards, on the cutting edges, one bevel each is ground on the cutting face, which bevel has a rake angle of −5° to −30°, and in a coating installation a second coating is applied on the ground bevel, which coating is especially resistant to cutting face wear (crater wear).

A tool treated and processed in this way obtains a resistant combination of coatings which is optimized with respect to abrasive wear and tear on the flank surface and crater wear on the cutting face. Through the grinding of the bevel, which takes place in a simple way through a surface grinding step along the respective cutting edge, the previously applied coating is removed in the region of this bevel. Obtained then is coated cutting flanks, coated cutting edges, bevel regions free of the coating, and coated flutes. The tool, provided with this first coating and having bevels ground on the cutting edges, is provided in a coating installation with a second coating that is resistant to crater wear. Generally such coatings, in particular e.g. Al₂O₃, can not yet be deposited optimally and in a well-adhering way to complex three-dimensional surfaces and edges owing e.g. to internal layer tensions. These problems do not arise on the surface-ground bevel. This surface-ground bevel on the cutting edges can thus be provided with such a coating in an optimal way.

The bevel on the respective cutting edge of the milling tool is ground such that the bevel has a rake angle of −5° to −30°, the bevel width being preferably smaller than 5% of the diameter of the tool. An optimal cutting effect is thereby obtained, in particular in the case of materials difficult to machine and at high removal rates. Of course it is also conceivable to put in the bevels on the cutting edges of a milling tool in such a way that they have different rake angles, whereby the occurrence of vibrations, which can manifest themselves through a whistling sound, can be effectively limited.

A coating of CrAlN (chromium aluminum nitride), TiAlN (titanium aluminum nitride) or TiAlCN (titanium aluminum carbonitride) can be applied as the first coating. Coatings of this kind, which are applied with a thickness of about 2 to 3 μm to the tool, have the desired resistance to wear.

Preferably this first coating is applied through vaporization according to the PVD (physical vapor deposition) method. An even coating is thereby obtained in an optimal way.

A diamond coating can also be used as the first coating for covering the surface of the tool. Here the surface of the tool to be coated is preferably roughened, which takes place in the case of carbide tools through a chemical etching of the cobalt phase, whereby a mechanical anchoring of the applied diamond coating to the surface of the tool can take place, whereby the diamond coating adheres to the corresponding surface in an optimal way. Such a diamond coating is very abrasion-resistant, but not very smooth, owing to the roughening of the substrate. The roughening step is not necessary with ceramic substrates.

Preferably this diamond coating is applied through vaporization according to the CVD (chemical vapor deposition) method, which again makes possible an even layer thickness. This coating has a thickness of about 6 μm.

A coating of α-Al₂O₃ (alpha aluminum oxide) is applied as the second coating with which the ground bevel with fine surface is covered, the PVD (physical vapor deposition) method being preferably used again. This second coating has a thickness of about 2 μm. It has a smooth surface, whereby the flowing away of the chips is optimal.

A diamond coating can also be applied as the second coating to the ground bevel. Here it is advantageous if the bevel is roughened before the coating, whereby once again a mechanical anchoring of the diamond layer on the roughened bevel is achieved. This diamond coating is once again applied to the bevel preferably by vaporization according to the CVD (chemical vapor deposition) method. With this diamond coating, a very abrasion-resistant bevel is obtained. Because the diamond coating adheres poorly to the first coating with which the cutting faces and the flanks are provided, it only remains on the bevel surface, and excessive rounding of the cutting edges through the relatively thick diamond layer can thereby be avoided, which is very advantageous for the machining process.

It is also conceivable, instead of the roughening of the bevel, to apply a smooth interim layer as an adhesive foundation on which a (fine) diamond coating is applied afterwards.

The second coating, typically adhering poorly on regions of the first coating, can be removed in areas where it is not desired through a wet jet process.

In the following, embodiment examples are described which were treated and processed with the method according to the invention.

### FIRST EXAMPLE

A tool to be treated and processed according to the inventive method is made up of a carbide and has four cutting flanks and four flutes, for example, each cutting flank being provided with a cutting edge on the cutting side. This tool is coated using the PVD (physical vapor deposition) method, CrAlN (chromium aluminum nitride) being used. Also suitable would be TiAlN (titanium aluminum nitride) or TiAlCN (titanium aluminum carbonitride). The coating thickness is 2 μm. Afterwards on each cutting edge a bevel is ground with a surface roughness Rₐ=0.05. This bevel has a rake angle of about −20°. With a tool diameter of 15 mm, the bevel width measures 0.6 mm. Also conceivable would be for the bevels of the four cutting edges of this tool to have different bevel angles. Afterwards, using the PVD method, a coating is applied to each bevel consisting of α-Al₂O₃ (alpha aluminum oxide). This coating is applied mainly to the bevel since the latter has a flat surface and can be easily coated. If this coating remains adhering to the adjacent regions, it does not matter. This material is then worn away relatively quickly during the machining processes, or it can be blasted away using a jet.

### SECOND EXAMPLE

A tool of carbide, again having four cutting flanks and four flutes, for example, each cutting flank again being provided with a cutting edge on the cutting side, is roughened over the entire surface. This takes place through the chemical etching of the cobalt phase, which always has as a consequence, however, a rounding of the edges, which is not desired. Afterwards, with the CVD (chemical vapor deposition) method, a diamond coating is applied to the entire surface, which diamond coating has a thickness of about 6 μm. With a surface grinding step, the cutting edges are subsequently provided with a bevel, the rake angle being about −20°, and whereby the rounding of the edges obtained through the etching is eliminated again. Here, too, the bevels can each have different rake angles. With a tool having a diameter of 15 mm, the width of the bevel is about 0.6 mm. Using the PVD method, applied to the ground bevel (surface roughness Rₐ=0.05) is a coating of α-Al₂O₃, which has a thickness of about 2 μm, and protects against crater wear. This material adheres poorly to the diamond coating, so that only the smoothly ground bevel is provided with the corresponding coating. Obtained with this treatment and processing method is a tool which has a very abrasion-resistant flank. Through the grinding of the bevels, a very fine surface is obtained in this region, whereby a notch effect upon tensile load is prevented in this region. A breaking off of the edge is avoided.

### THIRD EXAMPLE

The tool to be treated and processed according to the inventive method consists again of carbide, has four cutting flanks and four flutes, the cutting flanks each being provided with a cutting edge on the cutting side. This tool is provided with a base coat of CrAlN, which is applied according to the PVD method and has a thickness of about 2 μm. A coating of TiAlN or TiAlCN would also be suitable here. A bevel is ground afterwards on the cutting edges, which bevel has a rake angle of about −20°, it being possible for the bevels of the respective cutting edges to have different rake angles here too. With a tool diameter of 15 mm, the bevel has a width of about 0.6 mm. The bevel surfaces are subsequently roughened. Applied to these bevel surfaces using the CVD method is a diamond coating. This diamond coating adheres only to the roughened area of the bevels. This diamond coating has a thickness of typically about 6 μm, but nevertheless causes no rounding of the edges. The remaining areas of the tool have a fine surface. This tool is also very abrasion-resistant and wear-resistant.

With all the described examples, tools of ceramic, for example Si₃N₄ ceramic, can also be used instead of tools of carbide. The treatment and processing steps can also be carried out with these ceramic tools in an identical way as with the tools of carbide, a roughening of the surfaces to be coated not being necessary, however.

Likewise with all these described examples, the second coating, which adheres to regions of the surfaces where it is not desired, can be eliminated, for example through a wet jet process.

With this method according to the invention, tools can be obtained which are characterized by a high abrasion resistance and at the same time a resistance to crater wear, even when machining “difficult” materials and at very high removal rates.

1. A method for treatment and processing of tools for machining of workpieces by cutting, which tools are made up of a high-strength steel, carbide or ceramic, and are provided with at least one cutting flank and a flute, which cutting flank is provided with a cutting edge on the cutting side, wherein in a coating installation the tool is provided with a first coating that is resistant to flank wear, in that afterwards a bevel is ground on each of the cutting edges, which bevel has a rake angle of −5° to −30°, and in a coating installation a second coating is applied on the ground bevel, which coating is resistant to cutting face wear.

2. The method according to claim 1, wherein the ground bevel has a bevel width which is smaller than 5% of the diameter of the tool.

3. The method according to claim 1, wherein applied as a first coating is a coating of CrAlN, TiAlN or TiAlCN.

4. The method according to claim 3, wherein the first coating is applied by vaporization according to the PVD method.

5. The method according to claim 1, wherein the surface of the tool to be coated with the first coating is roughened, and in that a diamond coating is applied as the first coating.

6. The method according to claim 5, wherein the diamond coating is applied by vaporization according to the CVD method.

7. The method according to claim 1, wherein applied as the second coating is a coating of α-Al₂O₃ according to the PVD method.

8. The method according to claim 3 or 4, wherein the bevel is roughened, and a diamond coating is applied to the bevel as the second coating.

9. The method according to claim 8, wherein the diamond coating is applied by vaporization according to the CVD method.

10. The method according to claim 1, wherein the second coating adhering to regions of the first coating is removed by a wet jet process on regions where it is not desired.
